(19) United States
(12) Patent Application Publication
(10) Pub. No.: US 2024/0031720 A1
(43) Pub. Date: Jan. 25, 2024

(54) VOLUME CONTROLS

(71) Applicant: Hewlett-Packard Development Company, L.P., Spring, TX (US)

(72) Inventors: Shu-Chun Liao, Taipei (TW); Chang Chun Hsiung, Taipei (TW); Shih-Wei Lin, Taipei (TW)

(21) Appl. No.: 17/870,585

(22) Filed: Jul. 21, 2022

(51) Int. Cl. H04R 1/10; H04R 29/00; H03G 3/30

(52) U.S. Cl. CPC H04R 1/1041; H04R 29/001; H03G 3/3005; H04R 2430/01

(57) ABSTRACT

In some examples, a method includes determining, by a processor, an output volume based on a source gain and a volume setting. In some examples, the method includes, in response to determining that the output volume satisfies a volume threshold, determining, by the processor, a weight based on the output volume. In some examples, the method includes accumulating, by the processor, a weighted time value based on the weight. In some examples, the method includes controlling, by the processor, the output volume in response to determining that the weighted time value satisfies a time threshold.

### BACKGROUND

Electronic technology has advanced to become virtually ubiquitous in society and has been used for many activities in society. For example, electronic devices are used to perform a variety of tasks, including work activities, communication, research, and entertainment. Different varieties of electronic circuitry may be utilized to provide different varieties of electronic technology.

### BRIEF DESCRIPTION OF THE DRAWINGS

FIG. 1 is a flow diagram illustrating an example of a method for volume controls;

FIG. 2 is a flow diagram illustrating an example of a method for controlling output volume;

FIG. 3 is a block diagram of an example of an apparatus that may be used for volume controls;

FIG. 4 is a block diagram illustrating an example of a computer-readable medium for volume controls; and

FIG. 5 is a block diagram illustrating an example of components that may be utilized to control volume in accordance with some examples of the techniques described herein.

### DETAILED DESCRIPTION

Hearing can be negatively impacted when exposed to prolonged sound at high volume levels. Consumer electronics are often used to provide audio to users via headphones (e.g., earbuds, over-the-ear headphones, on-ear headphones, etc.) and/or speakers. Many people have suffered from hearing loss caused by prolonged exposure to sound via headphones and/or speakers. Hearing loss may be reduced and/or avoided by limiting volume of sound and/or duration of exposure to sound from electronic devices.

Some examples of the techniques described herein provide approaches to detect and/or control exposure to sound. Some challenges arise in attempting to control sound exposure. For instance, a wide variety of headphones (e.g., earbuds, over-the-ear headphones, in-ear headphones, closed-back headphones, open-back headphones, wireless headphones, Bluetooth headphones, analog headphones, etc.) may be used that vary in gain profile. Differences in gain profiles may lead to differences in actual output volume when device parameters (e.g., source gain and volume setting) are the same. Moreover, some approaches may fail to take a quantity of time exposure into account. Some examples of the techniques described herein may address (e.g., ameliorate) some of the issues with controlling sound exposure.

Throughout the drawings, identical or similar reference numbers may designate similar elements and/or may or may not indicate identical elements. When an element is referred to without a reference number, this may refer to the element generally, and/or may or may not refer to the element in relation to any Figure. The figures may or may not be to scale, and the size of some parts may be exaggerated to more clearly illustrate the example shown. Moreover, the drawings provide examples in accordance with the description. However, the description is not limited to the examples provided in the drawings.

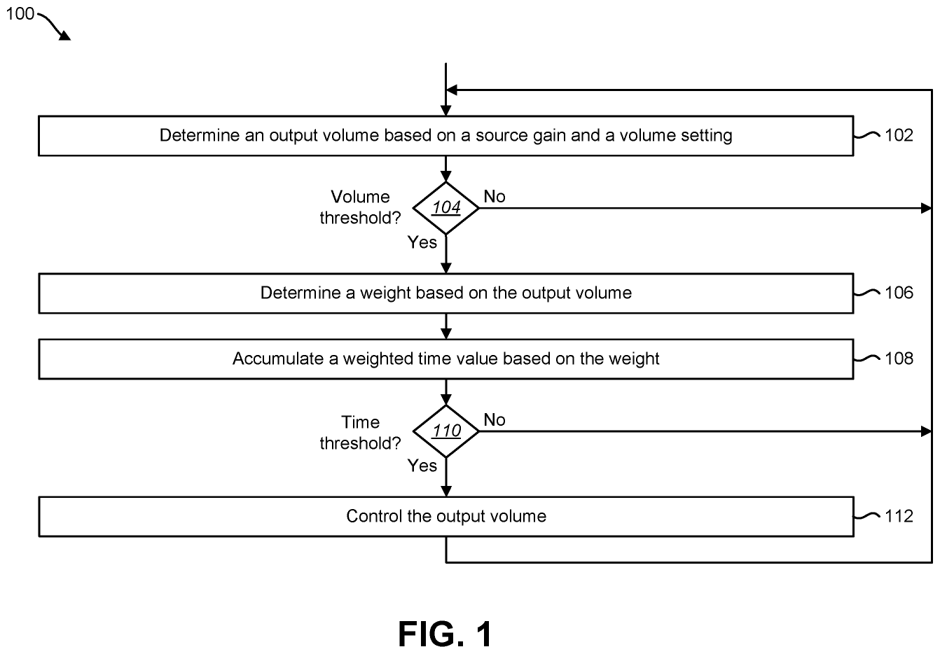

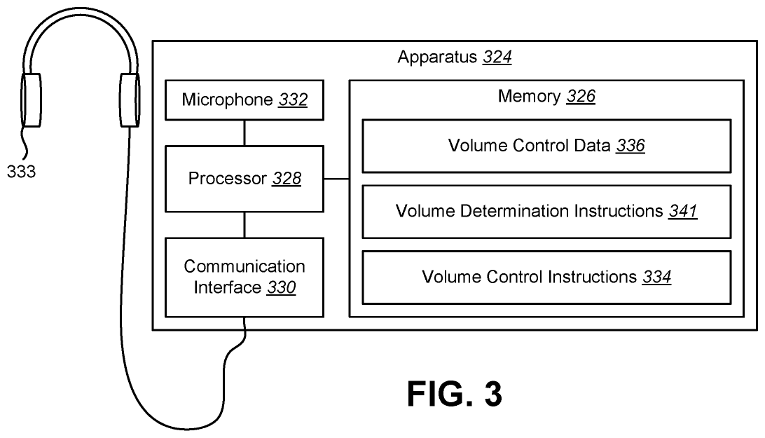

FIG. 1 is a flow diagram illustrating an example of a method 100 for volume controls. Volume is a quantity that characterizes sound pressure level, loudness, amplitude, and/or intensity. In some examples, volume may be expressed in decibels (dB). The method 100 and/or an element or elements of the method 100 may be performed by an apparatus (e.g., electronic device, computing device, smartphone, tablet device, laptop computer, server computer, etc.). For example, the method 100 may be performed by the apparatus 324 described in relation to FIG. 3.

The apparatus (e.g., a processor) may determine 102 an output volume based on a source gain and a volume setting. An output volume is a quantity representing a sound pressure level, loudness, amplitude, and/or intensity of sound output from a speaker. Volume (e.g., output volume) may be measured, calculated, and/or predicted.

Source gain is a quantity of gain (e.g., power ratio, dB gain, etc.) provided by a source. A source is an entity to produce audio (e.g., an audio signal, sound wave, etc.). Examples of a source may include an application (e.g., media player application, iTunes®, Windows Media Player, audio application, video player application, etc.) that is executable by a processor and/or an audio driver (e.g., instructions to interface with audio hardware, a sound card, integrated audio, etc.) that is executable by a processor. In some examples, a processor may obtain a source gain from an application and/or driver. For instance, a processor may request a gain of audio being produced by the application and/or driver.

A volume setting is a quantity representing a degree of audio amplification. For instance, a volume setting may indicate a degree of audio amplification provided by an apparatus (e.g., an operating system (OS) of an apparatus). In some examples, a volume setting may be expressed in a range of numbers (e.g., 1-80), a percentage (e.g., 5%, 27%, 51%, 100%, etc.), a gain (e.g., 10 dB), and/or a word (e.g., “Max,” “Min”), etc. In some examples, a volume setting may be adjustable via a user interface. In some examples, a processor may obtain a volume setting from an OS. For instance, the processor may query an OS to obtain a current volume setting.

In some examples, an apparatus may utilize a function and/or data structure to determine 102 the output volume. For instance, determining 102 the output volume may be based on a data structure that maps the source gain and the volume setting to the output volume. Some examples of a data structure include a table (e.g., lookup table), matrix, database, index, array, tree, etc. For instance, the data structure may associate a combination of a source gain and a volume setting with an output volume (e.g., measured output volume). In some examples, a data structure(s) may be stored in memory of the apparatus. In some examples, the data structure(s) and/or function(s) may be determined on the apparatus or received from another device (e.g., server, computer, audio device, etc.).

In some examples, the apparatus or another device may determine the data structure. For instance, the data structure may be determined by taking an output volume measurement from a microphone signal that captures a speaker output with a calibration source gain and a calibration volume setting. For example, the apparatus may populate the data structure with source gains corresponding to a calibration audio file (e.g., test audio file, trial audio file, audio samples with varying source gains, etc.). The apparatus may play the calibration audio file with a range of volume settings. For instance, the calibration audio file may be played through a speaker (e.g., earbuds, a headset, etc.) at various volume settings. A microphone may be located near the speaker. For instance, a user may hold an earbud next to (e.g., abutting) an integrated microphone of the apparatus, a headset microphone may be placed in a headset earcup, a microphone (that may be used in noise cancelation techniques, for instance) may be located near a headphone speaker, a wireless microphone may be attached to the speaker, etc. While the calibration audio file is output, the apparatus may obtain (e.g., receive, capture, etc.) a microphone signal that captures the speaker output. The apparatus may determine output volume measurements from the microphone signal. For instance, the apparatus may calculate gains in dB corresponding to various combinations of source gains and volume settings. Each output volume measurement may be stored in the data structure as an output volume in association with the corresponding source gain and volume setting. In some examples, interpolation may be utilized to provide an output volume between output volume measurements (e.g., corresponding to a source gain and/or volume setting between calibration values).

In some examples, the apparatus or another device may determine a function to associate the source gains and volume settings with the output volume measurements. For instance, a curve fit, regression, and/or machine learning may be performed based on the data to produce a function (e.g., model) to provide an output volume based on a source gain and a volume setting.

In some examples, determining a data structure and/or function based on output volume measurements may account for variations between different audio devices (which may have different connections, such as Bluetooth, Universal Serial Bus (USB), 3.5 millimeter (mm) audio jack, etc.). For instance, different audio devices and/or connections may vary by gain, which variation may be reflected in the data structure(s) and/or function(s). In some examples, different functions, different data structures and/or different portions of a data structure may correspond to different audio devices (e.g., headphones). For instance, a first table may indicate (e.g., may include, may be linked to) a headphone identifier(s). Some examples of a headphone identifier may include a vendor identifier (e.g., vendor identification number), a product identifier (e.g., product identification number), and/or a received identifier (e.g., a user-provided identifier, name, etc.). In some examples, the apparatus or another device may obtain (e.g., receive) an identifier through a digital interface (e.g., Bluetooth interface, Universal Serial Bus (USB) interface, Lightning interface, etc.), when an audio device is coupled to the apparatus or other device. In some examples, the apparatus or other device may obtain (e.g., receive) an identifier via an input interface (e.g., keyboard, touchscreen, microphone, etc.). For instance, a user may enter an identifier for an audio device coupled to the apparatus via an analog audio jack. An example of a data structure is given in Table (1). In some examples, Table (1) may indicate and/or be associated with an identifier (e.g., vendor identifier, product identifier, and/or name, etc.).

TABLE 1

| Source gain (dB) | Volume setting | Output volume (dB) |
|---|---|---|
| . | . | . |
| . | . | . |
| . | . | . |
| 66 | 50% | 47.5 |
| 70 | 50% | 50 |
| 80 | 50% | 55 |
| 86 | 50% | 57.5 |
| 90 | 50% | 60 |
| 94 | 50% | 65 |
| 100 | 50% | 70 |
| 110 | 50% | 80 |
| . | . | . |
| . | . | . |
| . | . | . |

In some examples, the apparatus may determine 102 the output volume by determining an output volume associated with the source gain and the volume setting in the data structure. For instance, the apparatus may utilize the source gain and volume setting to look up the associated output volume. In some examples, the apparatus may determine 102 the output volume by inputting the source gain and volume setting into a function, which may produce the output volume. In some examples, the output volume may correspond to audio that is currently being output by the apparatus.

The apparatus may determine 104 whether the output volume satisfies a volume threshold. A volume threshold may establish a level, above which sound may be monitored to trigger volume control and/or may damage hearing with an interval of exposure. For instance, sound that is under the volume threshold may not contribute toward triggering volume control in some approaches. Some examples of a volume threshold may include 60 dB, 65 dB, 70 dB, 72 dB, 75 dB, etc. In some examples, the volume threshold may be established based on empirical data (e.g., data that suggests hearing loss may occur above the volume threshold) and/or may be set based on an input (e.g., user input). In a case that the output volume does not satisfy the volume threshold, operation may return to determining 102 an output volume (for a next period, for instance).

In a case that the output volume satisfies the volume threshold, the apparatus may determine 106 a weight based on the output volume. For instance, the apparatus may determine a weight that is associated with the output volume. In some examples, determining 106 the weight may include selecting the weight based on a data structure that maps the output volume to the weight. In some examples, an apparatus may utilize a function and/or data structure to determine 106 the weight. For instance, determining the output volume may be based on a data structure that maps the output volume to the weight. For instance, the data structure may associate an output volume with a weight. In some examples, the data structure storing the weight may be a part of the data structure described above to store the source gains and volume settings. In some examples, the data structure storing the weight may separate from the data structure described above to store the source gains and volume settings. In some examples, weights in the data structure may be determined empirically and/or may be established based on an input (e.g., user input). An example of a data structure to store the weights is given in Table (2).

TABLE 2

| Volume (dB) | Weight |
|---|---|
| 70 | 1 |
| 80 | 2 |
| 90 | 3 |
| 100 | 4 |
| . | . |
| . | . |
| . | . |

The apparatus may accumulate 108 a weighted time value based on the weight. For instance, the weight may scale the time at a volume to produce the weighted time value. In accordance with the example of Table (2), 3 seconds of sound at 70 dB may produce 3 seconds of weighed time, 3 seconds of sound at 80 dB may produce 6 seconds of weighed time, or 3 seconds of sound at 100 dB may produce 12 seconds of weighed time, etc. For example, the apparatus may multiply a time (e.g., a period of time) at the output volume (e.g., average output volume over the period, maximum output volume in the period, etc.) by the weight. In some examples, accumulating 108 the weighted time value may include adding (e.g., summing) weighted times corresponding to a series of times (e.g., time periods) to produce the weighted time. For instance, the weighted time value may be a summation of weighted times.

The apparatus may determine 110 whether the weighted time value satisfies a time threshold. A time threshold may establish an interval, after which sound may be controlled to protect hearing. For instance, after the threshold time without volume control, additional sound may damage hearing. Some examples of a time threshold may include 30 minutes (e.g., 1800 seconds), 45 minutes, an hour, etc. In some examples, the time threshold may be established based on empirical data (e.g., data that suggests hearing loss may occur after the time threshold) and/or may be set based on an input (e.g., user input). In a case that the weighted time value does not satisfy the time threshold, operation may return to determining 102 an output volume (for a next period, for instance).

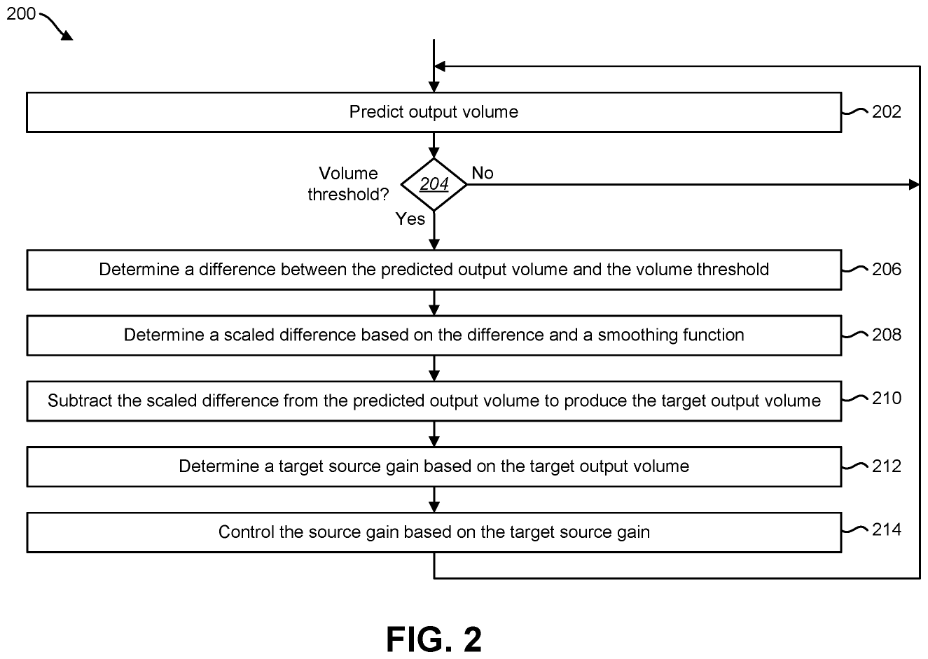

In a case that the weighted time value satisfies the time threshold, the apparatus may control 112 the output volume. For instance, the apparatus may limit and/or scale down the output volume. In some examples, the apparatus may control a source gain and/or a volume setting to control 112 the output volume. Some examples of techniques to control output volume are given in relation to FIG. 2. In some examples, operation may return to determining 102 an output volume after an interval of controlling 112 the output volume. For instance, once volume control is enabled, volume control may be performed for an interval (e.g., a threshold interval, 3 hours, 4 hours, etc.) and then may be disabled.

In some examples, an element(s) of the method 100 may be performed repeatedly and/or periodically. For instance, determining 102 an output volume and determining 104 whether the volume threshold is satisfied may be performed for each period (e.g., each three-second period) when sound is output.

FIG. 2 is a flow diagram illustrating an example of a method 200 for controlling output volume. In some examples, one, some, or all of the functions described in relation to FIG. 2 may be performed by the apparatus 324 described in relation to FIG. 3. For instance, the method 200 may be performed by an apparatus, electronic device, computing device, etc.

An apparatus may predict 202 an output volume. For instance, the apparatus may predict an output volume for a future period(s). In some examples, the apparatus may predict an output volume for a future period(s) (e.g., frame(s) ahead of a current output frame) using a buffered audio signal. In some examples, an apparatus may utilize a function and/or data structure to predict 202 the output volume. For instance, predicting 202 the output volume may be based on a data structure that maps a source gain and a volume setting to the output volume. In some examples, the apparatus may utilize the same function and/or data structure (used to determine 102 the output volume) for predicting 202 the output volume as similarly described in relation to FIG. 1 (for a future period(s), for instance). In some examples, the apparatus may utilize a current volume setting and a source gain(s) corresponding to a future period(s) to predict 202 the output volume(s). For instance, the apparatus may use source gains of 70 dB, 90 dB, 80 dB, 110 dB, 100 dB, and 70 dB corresponding to six future periods and a current volume setting of 50% to produce predicted output volumes of 50 dB, 60 dB, 55 dB, 80 dB, 70 dB, and 50 dB for the six future periods using Table (1).

The apparatus may determine 204 whether the output volume satisfies a volume threshold. In some examples, the volume threshold may be the same volume threshold (e.g., 60 dB, 65 dB, 70 dB, 72 dB, 75 dB, etc.) as described in relation to FIG. 1 or may be a different volume threshold. For example, the apparatus may compare the predicted output volume with the volume threshold to determine whether the predicted output volume is greater than the volume threshold. In a case that the predicted output volume does not satisfy the volume threshold, operation may return to predicting 202 an output volume (for a next period(s), for instance). For the six future periods in the example, for instance, the apparatus may determine that the predicted output volume for the fourth period, 80 dB, is greater than a volume threshold of 70 dB.

In a case that the volume threshold is satisfied, the apparatus may determine 206 a difference between the predicted output volume and the volume threshold. For instance, the apparatus may subtract the volume threshold from the predicted output volume to produce the difference. For the fourth period, for example, the apparatus may calculate 80 dB−70 dB=10 dB.

In some examples, the apparatus may determine a target output volume based on the difference. A target output volume is a volume targeted for output using volume control. In some examples, determining the target output volume may include determining 208 a scaled difference based on the difference and a smoothing function. A smoothing function is a function to smoothing adjustments in volume. For instance, the apparatus may apply a smoothing function to gradually adjust the output volume over time (which may reduce or avoid sudden changes in volume, for example). Some examples of a smoothing function may include a linear ramp function, a logarithmic function, a gaussian function, etc. For instance, a smoothing function may include 25% scaling two periods before a detected period (e.g., the period for which the volume threshold is exceeded), 50% scaling one period before the detected period, 100% scaling at the detected period, 50% scaling one period after the detected period, and 25% scaling two periods after the detected period.

A scaled difference is a difference with scaling applied. For instance, scaling from the smoothing function may be applied to the difference to produce a scaled difference. In some examples, the apparatus may determine 208 a scaled difference based on the difference (e.g., the difference at the detected period) and the smoothing function for a period(s) (e.g., detected period, previous period(s), subsequent period(s), etc.). For the second period (e.g., two periods before the detected period), for example, the scaling is 25% and the difference is 10 dB, thereby producing a scaled difference of 2.5 dB. For the third period (e.g., one period before the detected period), for example, the scaling is 50% and the difference is 10 dB, thereby producing a scaled difference of 5 dB. For the fourth period (e.g., the detected period), for example, the scaling is 100% and the difference is 10 dB, thereby producing a scaled difference of 10 dB. For the fifth period (e.g., period after the detected period), for example, the scaling is 50% and the difference is 10 dB, thereby producing a scaled difference of 5 dB. For the sixth period (e.g., two periods after the detected period), for example, the scaling is 25% and the difference is 10 dB, thereby producing a scaled difference of 2.5 dB.

In some examples, determining the target output volume may include subtracting 210 the scaled difference from the predicted output volume to produce the target output volume. For instance, each scaled difference may be subtracted from a corresponding predicted output volume to produce a respective target output volume for each period. For the second period (e.g., two periods before the detected period), for example, the predicted output volume is 60 dB and the scaled difference is 2.5 dB, resulting in a target output volume of 57.5 dB. For the third period (e.g., one period before the detected period), for example, the predicted output volume is 55 dB and the scaled difference is 5 dB, resulting in a target output volume of 50 dB. For the fourth period (e.g., the detected period), for example, the predicted output volume is dB and the scaled difference is 10 dB, resulting in a target output volume of dB. For the fifth period (e.g., period after the detected period), for example, the predicted output volume is 70 dB and the scaled difference is 5 dB, resulting in a target output volume of 65 dB. For the sixth period (e.g., two periods after the detected period), for example, the predicted output volume is 50 dB and the scaled difference is 2.5 dB, resulting in a target output volume of 47.5 dB.

The apparatus may determine 212 a target source gain based on the target output volume. A target source gain is a source gain to produce a target output volume. For instance, the apparatus may determine a target source gain based on a function and/or data structure that maps the target output volume (and a volume setting, for instance) to a target source gain. In some examples, the apparatus may determine target source gain(s) for a future period(s) using the target output volume(s). For instance, determining 212 the target source gain may be based on a data structure that maps a target output volume and a volume setting to the target source gain. In some examples, the apparatus may utilize the same function and/or data structure (used to determine 102 the output volume) for determining 212 the target source gain (for a future period(s), for instance). In some examples, the apparatus may utilize a current volume setting and a target output volume(s) corresponding to a future period(s) to determine 212 the target source gain(s). For instance, the apparatus may use target output volumes of 57.5 dB, 50 dB, 70 dB, 65 dB, and 47.5 dB corresponding to the second through sixth future periods and a current volume setting of 50% to produce target source gains of 86 dB, 70 dB, 100 dB, 94 dB, and 66 dB for the second through sixth future periods using Table (1).

The apparatus may control 214 the source gain based on the target source gain. For instance, the apparatus may adjust the source gain to the target source gain. In some examples, the source gain for each period may be adjusted to a corresponding target source gain. In some examples, controlling the source gain based on the target source gain may result in adjusting the output volume to the target output volume.

In some examples, the apparatus may determine a target volume setting based on the target output volume. A target volume setting is a volume setting to produce a target output volume. For instance, the apparatus may determine a target volume setting based on a function and/or data structure that maps the target output volume (and a source gain or target source gain, for instance) to a target volume setting. In some examples, a technique(s) described herein relative to a target source gain may instead be performed relative to a target volume setting. In some examples, a technique(s) described herein relative to a target source gain may be performed relative to a combination of a target source gain and a target volume setting.

FIG. 3 is a block diagram of an example of an apparatus 324 that may be used for volume controls. The apparatus 324 may be a computing device, such as a personal computer, a server computer, a smartphone, a tablet computer, etc. The apparatus 324 may include and/or may be coupled to a processor 328, a communication interface 330, a memory 326, and/or a microphone 332. In some examples, the apparatus 324 may be in communication with (e.g., coupled to, have a communication link with) another device (e.g., audio device, headphones, server, remote device, another apparatus, etc.). The apparatus 324 may include additional components (not shown) and/or some of the components described herein may be removed and/or modified without departing from the scope of the disclosure.

The processor 328 may be any of a central processing unit (CPU), a semiconductor-based microprocessor, graphics processing unit (GPU), field-programmable gate array (FPGA), an application-specific integrated circuit (ASIC), and/or other hardware device suitable for retrieval and execution of instructions stored in the memory 326. The processor 328 may fetch, decode, and/or execute instructions stored on the memory 326. In some examples, the processor 328 may include an electronic circuit or circuits that include electronic components for performing a functionality or functionalities of the instructions. In some examples, the processor 328 may perform one, some, or all of the aspects, elements, techniques, etc., described in relation to one, some, or all of FIGS. 1-5.

The memory 326 is an electronic, magnetic, optical, and/or other physical storage device that contains or stores electronic information (e.g., instructions and/or data). The memory 326 may be, for example, Random Access Memory (RAM), Electrically Erasable Programmable Read-Only Memory (EEPROM), a storage device, an optical disc, and/or the like. In some examples, the memory 326 may be volatile and/or non-volatile memory, such as Dynamic Random Access Memory (DRAM), EEPROM, magnetoresistive random-access memory (MRAM), phase change RAM (PCRAM), memristor, flash memory, and/or the like. In some examples, the memory 326 may be a non-transitory tangible machine-readable storage medium, where the term “non-transitory” does not encompass transitory propagating signals. In some examples, the memory 326 may include multiple devices (e.g., a RAM card and a solid-state drive (SSD)).

The apparatus 324 may include a communication interface 330 through which the processor 328 may communicate with an external device or devices (not shown), for instance, to receive and store volume control data 336. The communication interface 330 may include hardware and/or machine-readable instructions to enable the processor 328 to communicate with the external device or devices. The communication interface 330 may enable a wired or wireless connection to the external device or devices. The communication interface 330 may further include a network interface card and/or may also include hardware and/or machine-readable instructions to enable the processor 328 to communicate with various input and/or output device(s), such as a keyboard, a mouse, a display, headphones 333, another apparatus, electronic device, computing device, printer, etc. In some examples, an input device may be utilized by a user to input instructions into the apparatus 324. In some examples, the apparatus 324 may include headphones and/or may be coupled to headphones 333 (via the communication interface 330, for instance).

In some examples, the memory 326 may store volume control data 336. In some examples, the volume control data 336 may include a function(s) and/or data structure(s) described herein. In some examples, the volume control data 336 (e.g., a portion of the volume control data 336) may be determined based on a signal obtained (e.g., captured, received, etc.) from a microphone 332. For example, the processor 328 may execute instructions (not shown in FIG. 3) to determine output volumes based on a microphone signal. In some examples, the apparatus 324 (e.g., processor 328) may utilize a display to present a message requesting a user to plug in headphones 333 and/or to hold the headphones 333 (e.g., an earcup) near the microphone 332. The apparatus 324 (e.g., processor 328) may detect when the headphones 333 are coupled and may play a calibration audio file with set calibration volume settings (e.g., a range of volume settings). The apparatus 324 (e.g., processor 328) may record a signal from the microphone 332. For instance, the apparatus 324 may determine output volumes based on a signal from headphones 333 captured utilizing an integrated microphone 332 and/or an external microphone via the communication interface 330. In some examples, the output volumes may be stored in association with source gains and volume settings in the volume control data 336. For instance, the processor 328 may determine a data structure by associating a calibration source gain and a calibration volume setting with an output volume measurement from a microphone signal that indicates a speaker (e.g., headphone 333) output. For instance, the apparatus 324 (e.g., processor 328) may create a volume mapping matrix and store the volume mapping matrix as a profile associated with the headphones 333 (e.g., with a headphone identifier).

The memory 326 may store volume determination instructions 341. For example, the volume determination instructions 341 may be instructions for determining an output volume. In some examples, the processor 328 may execute the volume determination instructions 341 to obtain a source gain and/or to obtain a volume setting from an OS. In some examples, obtaining the source gain and/or the volume setting may be performed as described in relation to FIG. 1 and/or FIG. 2. In some examples, the processor 328 may obtain the source gain from an audio driver. In some examples, the processor 328 may obtain the source gain from an application.

In some examples, the processor 328 may execute the volume determination instructions 341 to determine an output volume based on a source gain and a volume setting. In some examples, determining the output volume may be performed as described in relation to FIG. 1 and/or FIG. 2. For instance, the processor 328 may look up the output volume in the data structure based on the source gain and the volume setting to determine the output volume.

In some examples, the processor 328 may execute the volume determination instructions 341 to weight a time of the output volume to produce a weighted time value. In some examples, weighting a time of the output volume may be performed as described in relation to FIG. 1 and/or FIG. 2. For instance, the processor 328 may look up a weight associated with the output volume to produce a weighted time, which may be accumulated with another weighted time(s) corresponding to another period(s) to produce the weighted time value.

In some examples, the processor 328 may execute the volume determination instructions 341 to, in response to determining that the weighted time value satisfies a time threshold, determine a predicted output volume of a period. In some examples, determining the predicted output volume may be performed as described in relation to FIG. 1 and/or FIG. 2. For instance, the processor 328 may look up the predicted output volume in the data structure based on the source gain of a future period and the volume setting to determine the predicted output volume.

In some examples, the memory 326 may store volume control instructions 334. The volume control instructions 334 may be instructions for controlling an output volume of the apparatus 324 (e.g., output volume provided to the headphones 333). In some examples, the processor 328 may execute the volume control instructions 334 to adjust a second source gain of the period in response to determining that the predicted output volume meets a volume threshold. In some examples, adjusting the second source gain may be performed as described in relation to FIG. 1 and/or FIG. 2. For instance, the processor 328 may determine a difference between the predicted output volume and the volume threshold, may determine a scaled difference based on the difference and a smoothing function, may determine a target output volume based on the scaled difference, may determine a target source gain based on the scaled difference, and may adjust the second source gain to the target source gain for the period.

In some examples, the apparatus 324 may output a sound based on the second source gain. For instance, the apparatus 324 (e.g., processor 328 and/or communication interface 330) may output a sound with the second source gain via the headphones 333.

In some examples, the processor 328 may execute the volume control instructions 334 to adjust a third source gain of a previous period and may adjust a fourth source gain of a subsequent period based on the smoothing function and the difference between the predicted output volume and the volume threshold. In some examples, adjusting the third source gain and the fourth source gain may be performed as described in relation to FIG. 1 and/or FIG. 2. For instance, the processor 328 may adjust source gains for periods before and after the period (e.g., detected period). In some examples, the smoothing function may increase scaling from the previous period to the period (e.g., detected period). In some examples, the smoothing function may decrease scaling from the period (e.g., detected period) to the subsequent period. For instance, the smoothing function may ramp up as it approaches a period with a predicted output volume that is greater than the volume threshold and/or may ramp down as it passes the period.

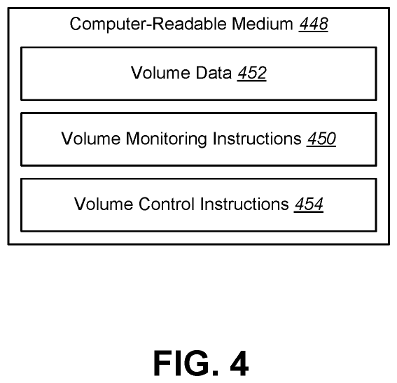

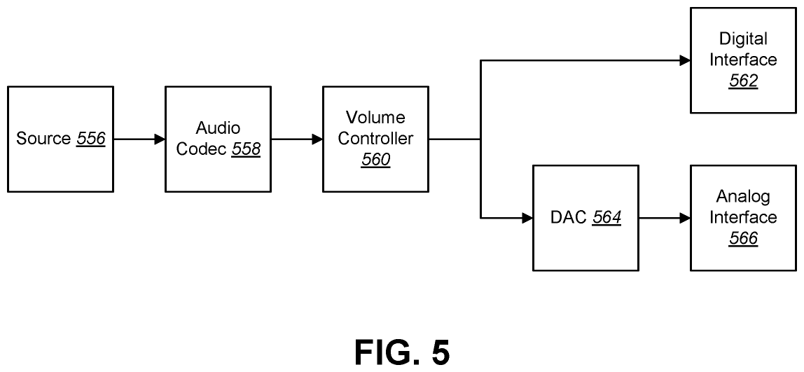

FIG. 4 is a block diagram illustrating an example of a computer-readable medium 448 for volume controls. The computer-readable medium 448 is a non-transitory, tangible computer-readable medium. The computer-readable medium 448 may be, for example, RAM, EEPROM, a storage device, an optical disc, and the like. In some examples, the computer-readable medium 448 may be volatile and/or non-volatile memory, such as DRAM, EEPROM, MRAM, PCRAM, memristor, flash memory, and the like. In some examples, the memory 326 described in relation to FIG. 3 may be an example of the computer-readable medium 448 described in relation to FIG. 4. In some examples, the computer-readable medium may include code, instructions and/or data to cause a processor to perform one, some, or all of the operations, aspects, elements, etc., described in relation to one, some, or all of FIG. 1, FIG. 2, FIG. 3, FIG. 4, and/or FIG. 5.

The computer-readable medium 448 may include code (e.g., data, executable code, and/or executable instructions). For example, the computer-readable medium 448 may include volume data 452, volume monitoring instructions 450, and/or volume control instructions 454.

The volume data 452 may include a data structure(s) that associate measured output volumes with respective source gains and volume settings. For instance, the volume data 452 may include a table(s) that associates measured output volumes with source gains and volume settings for an audio device(s). In some examples, the volume data 452 may include a table(s) that associates weights with respective output volumes. In some examples, the data structure(s) may be determined and/or structured as described in relation to FIG. 1, FIG. 2, and/or FIG. 3.

The volume monitoring instructions 450 may include instructions, that when executed, cause a processor of an electronic device to determine, from a first table, a first output volume based on a source gain and a first volume setting. The first table may be stored in the volume data 452. In some examples, the first table may indicate a headphone identifier(s). For instance, the first table may be determined based on measurements taken using first headphones associated with a first headphone identifier and/or the first table may be utilized (e.g., selected) to determine the first output volume when first headphones with a first headphone identifier are utilized. In some examples, another table may be generated and/or utilized (e.g., selected) in conjunction with another set of headphones. In some examples, determining the first output volume may be performed as described in relation to FIG. 1, FIG. 2, and/or FIG. 3.

The volume monitoring instructions 450 may include instructions, that when executed, cause the processor of the electronic device to determine a weight based on the output volume from a second table in response to a determination that the first output volume satisfies a volume threshold. The second table may be stored in the volume data 452. In some examples, determining the weight may be performed as described in relation to FIG. 1, FIG. 2, and/or FIG. 3.

The volume monitoring instructions 450 may include instructions, that when executed, cause a processor of the electronic device to accumulate a weighted time value based on the weight. In some examples, accumulating the weighted time value may be performed as described in relation to FIG. 1, FIG. 2, and/or FIG. 3.

The volume monitoring instructions 450 may include instructions, that when executed, cause a processor of the electronic device to produce, from the first table, a predicted output volume in response to a determination that the weighted time value meets a time threshold. In some examples, producing the predicted output volume may be performed as described in relation to FIG. 1, FIG. 2, and/or FIG. 3.

The volume control instructions 454 may include instructions, that when executed, cause a processor of the electronic device to control a second output volume (e.g., a second output volume after the first output volume) based on the predicted output volume and the volume threshold. In some examples, controlling the second output volume may be performed as described in relation to FIG. 1, FIG. 2, and/or FIG. 3. For instance, the volume control instructions 454 may include instructions, that when executed, cause a processor of the electronic device to determine a difference between the volume threshold and the predicted output volume, to determine a target output volume based on the difference, and/or to determine, from the first table, a target source gain based on the target output volume and a second volume setting. In some examples, a target volume setting may be determined. For instance, a target volume setting may be determined (in addition to a target source gain or instead of a target source gain, for example) to produce the target output volume. The second volume setting may be the same as the first volume setting or different from the first volume setting. For instance, a current volume setting may have changed since the first volume setting was utilized to determine the first output volume. In some examples, a source gain of the electronic device may be set to the target source gain, which may cause the electronic device to output sound at the target output volume.

FIG. 5 is a block diagram illustrating an example of components that may be utilized to control volume in accordance with some examples of the techniques described herein. The components include a source 556, an audio codec 558, a volume controller 560, a digital interface 562, a digital-to-analog converter (DAC) 564, and/or an analog interface. In some examples, the source 556, audio codec 558, volume controller 560, digital interface 562, DAC 564, and/or analog interface 566 may be included in the apparatus 324 described in relation to FIG. 3. Each component may be implemented in hardware (e.g., circuitry) or a combination of hardware and instructions (e.g., a processor with executable instructions).

The source 556 may provide encoded audio to the audio codec 558. The audio codec 558 may decode the audio to produce decoded audio (e.g., a digital audio signal). The decoded audio may be provided to the volume controller 560. The volume controller 560 may control the volume of the decoded audio as described in relation to FIG. 1, FIG. 2, FIG. 3, and/or FIG. 4. For instance, the volume controller 560 may provide volume protection by lowering source gain and/or volume settings for the audio bit stream in some cases. The volume controller 560 may produce decoded audio with controlled (e.g., limited) volume to provide an output volume at a safe level. For instance, the volume of the decoded audio may be limited to 70 dB after a time threshold is reached. The decoded audio with controlled volume may be provided to the digital interface 562 and/or DAC 564.

The digital interface 562 may include hardware and/or instructions to interface digitally with a digital audio device (e.g., headphones). For instance, the digital interface 562 may be a Bluetooth and/or USB interface to provide a digital audio signal to a digital audio device.

The DAC 564 may convert the decoded audio signal from a digital signal to an analog signal (e.g., analog audio signal). The analog audio signal may be provided to the analog interface 566. The analog interface 566 may include hardware to interface with an audio device (e.g., headphones). For instance, the analog interface 566 may be a 3.5 mm audio jack to provide an analog audio signal to an audio device.

As used herein, the term “and/or” may mean an item or items. For example, the phrase “A, B, and/or C” may mean any of: A (without B and C), B (without A and C), C (without A and B), A and B (but not C), B and C (but not A), A and C (but not B), or all of A, B, and C.

While various examples are described herein, the disclosure is not limited to the examples. Variations of the examples described herein may be implemented within the scope of the disclosure. For example, aspects or elements of the examples described herein may be omitted or combined.

What is claimed is:

1. A method, comprising:
determining, by a processor, an output volume based on a source gain and a volume setting;
in response to determining that the output volume satisfies a volume threshold, determining, by the processor, a weight based on the output volume;
accumulating, by the processor, a weighted time value based on the weight; and
controlling, by the processor, the output volume in response to determining that the weighted time value satisfies a time threshold.

2. The method of claim 1, wherein determining the output volume is based on a data structure that maps the source gain and the volume setting to the output volume.

3. The method of claim 2, wherein the data structure is determined by taking an output volume measurement from a microphone signal that captures a speaker output with a calibration source gain and a calibration volume setting.

4. The method of claim 1, wherein determining the weight comprises selecting the weight based on a data structure that maps the output volume to the weight.

5. The method of claim 1, wherein accumulating the weighted time value comprises multiplying a time at the output volume by the weight.

6. The method of claim 1, wherein controlling the output volume comprises:
determining that a predicted output volume satisfies a second volume threshold;
determining a difference between the predicted output volume and the volume threshold; and
determining a target output volume based on the difference.

7. The method of claim 6, wherein determining the target output volume comprises:
determining a scaled difference based on the difference and a smoothing function at a first period; and
subtracting the scaled difference from the predicted output volume to produce the target output volume at the first period.

8. The method of claim 7, further comprising:
determining a target source gain based on a data structure that maps the target output volume to the target source gain; and
adjusting the source gain to the target source gain at the first period.

9. The method of claim 7, further comprising:
determining a second scaled difference based on the difference and the smoothing function at a second period; and
subtracting the second scaled difference from a second predicted output volume at the second period to produce a second target output volume.

10. An apparatus, comprising:
a memory; and
a processor coupled to the memory, wherein the processor is to:
obtain a source gain;
obtain a volume setting from an operating system (OS);
determine an output volume based on the source gain and the volume setting;
weight a time of the output volume to produce a weighted time value;
in response to determining that the weighted time value satisfies a time threshold, determine a predicted output volume of a period; and
adjust a second source gain of the period in response to determining that the predicted output volume meets a volume threshold.

11. The apparatus of claim 10, wherein the processor is to adjust a third source gain of a previous period and is to adjust a fourth source gain of a subsequent period based on a smoothing function and a difference between the predicted output volume and the volume threshold.

12. The apparatus of claim 11, wherein the smoothing function is to increase scaling from the previous period to the period.

13. The apparatus of claim 11, wherein the smoothing function is to decrease scaling from the period to the subsequent period.

14. The apparatus of claim 10, wherein the processor is to determine a data structure by associating a calibration source gain and a calibration volume setting with an output volume measurement from a microphone signal that indicates a speaker output.

15. The apparatus of claim 14, wherein the processor is to look up the output volume in the data structure based on the source gain and the volume setting to determine the output volume.

16. The apparatus of claim 10, wherein the processor is to obtain the source gain from an audio driver.

17. The apparatus of claim 10, wherein the processor is to obtain the source gain from an application.

18. A non-transitory tangible computer-readable medium comprising instructions when executed cause a processor of an electronic device to:
determine, from a first table, a first output volume based on a source gain and a first volume setting;
in response to a determination that the first output volume satisfies a volume threshold, determine a weight based on the output volume from a second table;
accumulate a weighted time value based on the weight;
produce, from the first table, a predicted output volume in response to a determination that the weighted time value meets a time threshold; and
control a second output volume based on the predicted output volume and the volume threshold.

19. The non-transitory tangible computer-readable medium of claim 18, wherein the first table indicates a headphone identifier.

20. The non-transitory tangible computer-readable medium of claim 18, wherein the instructions when executed cause the processor to:
determine a difference between the volume threshold and the predicted output volume;
determine a target output volume based on the difference; and
determine, from the first table, a target source gain based on the target output volume and a second volume setting.
